(19) United States
(12) Patent Application Publication
(10) Pub. No.: US 2006/0054987 A1
(43) Pub. Date: Mar. 16, 2006

(54) Photoelectric conversion device, image pickup device, and method for applying electric field to the same

(75) Inventor: Kazumi Nii, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/213,747

(22) Filed: Aug. 30, 2005

(30) Foreign Application Priority Data
Aug. 31, 2004 (JP) P.2004-251538
Mar. 9, 2005 (JP) P.2005-065215

(51) Int. Cl. H01L 31/00; H01L 31/0232; H01L 31/062; H01L 29/08; H01L 31/113

(52) U.S. Cl. 257/440; 257/294; 257/291; 257/435; 257/40

(57) ABSTRACT

A photoelectric conversion device comprises an organic photoelectric conversion film intervening between at least two electrodes, the organic photoelectric conversion film comprising a positive hole transporting photoelectric conversion film and an electron transporting photoelectric conversion film, wherein each of the positive hole transporting photoelectric conversion film and the electron transporting photoelectric conversion film has absorption in a visible range, and a difference in wavelength between longer wavelength ends of absorption of the positive hole transporting photoelectric conversion film and the electron transporting photoelectric conversion film is 50 nm or less.

### BACKGROUND OF THE INVENTION

1. Field of the Invention

The present invention relates to such a photoelectric conversion film that sharp spectral characteristics, a photoelectric conversion device having the photoelectric conversion film, a solid image pickup device, and a method for applying an electric field to them.

2. Description of the Related Art

A photoelectric conversion film has been widely utilized, for example, as a light sensor, and in particular, it is preferably used as a solid image pickup device (light receiving device) for an imaging apparatus (solid imaging apparatus), such as a television camera. As a material for a photoelectric conversion film used as a solid image pickup device of an imaging apparatus, a film of an inorganic material, such as an Si film and an a-Se film, has been used.

The conventional photoelectric conversion film using the inorganic material has such a photoelectric conversion capability that has no steep wavelength dependency. Therefore, it is the mainstream that an imaging apparatus using the inorganic material as a photoelectric conversion film has a three-plate structure containing three photoelectric conversion films disposed behind a prism for dividing incident light into three primary colors, i.e., red, green and blue.

However, the imaging apparatus having the three-plate structure necessarily suffers increase in dimension and weight due to the structure thereof.

In order to reduce the size and weight of the imaging apparatus, one having a single plate structure having only one light receiving device without a spectral prism provided is demanded, and for example, an imaging apparatus having such a structure has been put into practical use and popularized that has red, green and blue filters are applied to a single plate light receiving device. However, the device has a complex structure due to the red, green and blue filters and micro lenses or the like for improving the light condensing ratio, which are laminated in the device, and the device is inferior in utilization efficiency of light. As a measure using no filter, such a device is proposed that has photoelectric conversion films each having red, green and blue spectral characteristics, respectively, and a device using an organic material as the photoelectric conversion film is promising as a device capable of freely designing the light absorption characteristics.

Representative examples where an organic material is used as a photoelectric conversion film include electrophotography and a solar cell, and various materials therefor have been investigated. Examples of the material for electrophotography include the materials disclosed in Kock-Yee Law, Chem. Rev., vol. 93, p. 449 (1993), and the material for a solar cell include the material disclosed in S. R. Forrest, J. Appl. Phys., vol. 93, p. 3693 (2003). The materials disclosed in these literatures have a broad absorption spectrum as a film to provide a broad photoelectric conversion spectrum, which shows the wavelength dependency of the photoelectric conversion capability, and thus they fail to have such a sharp wavelength dependency that can provide spectral capability into red, green and blue colors.

A light receiving device using an organic film capable providing spectral capability into red, green and blue is disclosed, for example, in JP-T-2002-502120, JP-A-2003-158254, JP-A-2003-234460 and S. Aihara, Appl. Phys. Lett., vol. 82, p. 511 (2003). In these literatures, a red, green or blue spectral photoelectric conversion spectrum is such a photoelectric conversion spectrum that is derived from one kind of photoelectric conversion material constituting the photoelectric conversion layer, or in alternative, both a p-type photoelectric conversion material and an n-type photoelectric conversion material contribute to photoelectric conversion. However, the resulting photoelectric conversion spectrum has intensity in plural ranges among red, green and blue colors. For example, the example of JP-A-2003-234460 discloses a polysilane film having coumarin 6 dispersed therein having photosensitivity over a blue range at a wavelength of 500 nm or less, and a polysilane film having rhodamine 6G dispersed therein having photosensitivity in a green range. In the devices, however, coumarin 6 and rhodamine 6G function as a photoelectric conversion material, but polysilane does not function, so as to provide a low internal quantum efficiency of photoelectric conversion of 1. A device using a film of zinc phthalocyanine and tris-8-hydroxyquinoline aluminum as a photoelectric conversion film has insufficient spectral characteristics since it has absorption ranges in a red range and a blue range although the internal quantum efficiency thereof is as relative high as 20%. Accordingly, in order to provide use the device as an image pickup device, the spectral characteristics, luminescent efficiency and device durability thereof are insufficient, and improvements have been demanded.

### SUMMARY OF THE INVENTION

An object of the invention is to provide such a photoelectric conversion film, a photoelectric conversion device and a image pickup device (preferably, a color image sensor) that have a narrow half-value width of absorption and are excellent in color reproducibility, and to provide such a photoelectric conversion film, a photoelectric conversion device and a image pickup device that have a high photoelectric conversion-efficiency and are excellent in durability.

The objects of the invention are attained by the following means.

(1) A photoelectric conversion device containing: an organic photoelectric conversion film intervening between at least two electrodes, the organic photoelectric conversion film containing at least a positive hole transporting photoelectric conversion film and an electron transporting photoelectric conversion film, wherein each of the positive hole transporting photoelectric conversion film and the electron transporting photoelectric conversion film has absorption in a visible range, and a difference in wavelength between longer wavelength ends of absorption of the positive hole transporting photoelectric conversion film and the electron transporting photoelectric conversion film is 50 nm or less.

(2) The photoelectric conversion device as described in the item (1), wherein a film absorption spectrum of the organic photoelectric conversion film has an absorption maximum on the longest wavelength side having a half-value width of from 50 to 150 nm.

(3) The photoelectric conversion device as described in the item (1) or (2), wherein the organic photoelectric conversion film has a film absorption spectrum in at least one range of blue light, green light and red light in a wavelength range of 400 nm or more, and the absorption spectrum in the range has an absorption maximum having a maximum value of three times or more a maximum value of an absorption maximum in a wavelength range outside the range.

(4) The photoelectric conversion device as described in one of the items (1) to (3), wherein the organic photoelectric conversion film has a photoelectric conversion spectrum (which indicates a spectrum sensitivity) having a maximum value at a wavelength of from 420 to 480 nm, from 510 to 570 nm, or from 600 to 660 nm.

(5) The photoelectric conversion device as described in one of the items (1) to (4), wherein the film of the electron transport material is in a crystalline state.

(6) The photoelectric conversion device as described inone of the items (1) to (5), wherein an ionization potential (Ip₁) and an electron affinity (Ea₁) of the positive hole transporting photoelectric conversion film and an ionization potential (Ip₂) and an electron affinity (Ea₂) of the electron transporting photoelectric conversion film satisfy relationships Ip₂<Ip₂ and Ea₁<Ea₂.

(7) The photoelectric conversion device as described in one of the items (1) to (6), wherein the photoelectric conversion device further contains at least one charge transporting layer transporting positive holes or electrons formed in the organic photoelectric conversion layer, and the charge transporting layer has absorption having a longer wavelength end at a wavelength shorter than an absorption maximum wavelength of the organic photoelectric conversion film.

(8) The photoelectric conversion device as described in the item (7), wherein at least one of materials constituting the charge transporting layer is a compound represented by the following general formula (I)
L [symbol] A)ₘ (I)
wherein A represents a heterocyclic ring containing two or more aromatic heterocyclic rings condensed to each other, provided that plural heterocyclic rings represented by A are the same as or different from each other; m represents an integer of 2 or more; and L represents a linking group.

(9) The photoelectric conversion device as described in the item (7) or (8), wherein the material constituting the charge transporting layer is a compound represented by the following general formula (III) 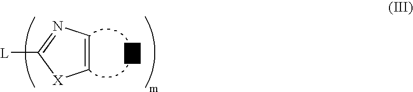
wherein X represents O, S, Se, Te or N—R; R represents a hydrogen atom, an aliphatic hydrocarbon group, an aryl group or a heterocyclic group; Q₃ represents an atomic group forming an aromatic heterocyclic ring (preferably, a nitrogen-containing aromatic heterocyclic ring); m represents an integer of 2 or more; and L represents a linking group.

(10) An image pickup device containing at least one of the photoelectric conversion device as described in one of the items (1) to (9)

(11) The image pickup device as described in the item (10), wherein the photoelectric conversion device has a maximum of a photoelectric conversion spectrum in a green light range.

(12) The image pickup device as described in the item (10), wherein the image pickup device has at least three of the photoelectric conversion devices, and the photoelectric conversion devices have maxima of photoelectric spectra in a blue light range, a green light range and a red light range, respectively.

(13) A method for applying an electric field to a photoelectric conversion device, the method containing a step of applying an electric field of from 10 to 1×10¹² V/m to the photoelectric conversion device or the image pickup device as described in one of the items (1) to (12), and a device being applied with an electric field of 10 V/m to 1×10¹² V/m, the device being the photoelectric conversion device or the image pickup device as described in one of the items (1) to (12).

(14) A device containing at least two electromagnetic wave absorbing and photoelectric conversion parts, at least one of the parts containing the image pickup device as described in one of the items (10) to (13).

(15) The device as described in the item (14), wherein the at least two electromagnetic wave absorbing and photoelectric conversion parts have a laminate structure of at least two layers.

(16) The device as described in the item (15), wherein an upper layer of said at least two layers comprises a portion capable of photoelectric conversion by absorbing green light.

(17) A device containing at least three electromagnetic wave absorbing and photoelectric conversion parts, at least one of the parts containing the image pickup device as described in one of the items (10) to (13).

(18) The device as described in the item (17), wherein said at least three electromagnetic wave absorbing and photoelectric conversion parts have a laminate structure of at least three layers, and an upper layer of said at least three layers comprises a portion capable of a photoelectric conversion by absorbing green light.

(19) The device as described in the item (17) or (18), wherein at least two of said at least three electromagnetic wave absorbing and photoelectric conversion parts are formed by inorganic layers.

(20) The device as described in the item (17) or (18), wherein at least two of said at least three electromagnetic wave absorbing and photoelectric conversion parts are formed in a silicon substrate.

### BRIEF DESCRIPTION OF THE DRAWINGS

FIG. 1 is a schematic cross sectional view showing an embodiment of one pixel of a BGR three-layer laminated photoelectric conversion image pickup device according to the invention; and

FIG. 2 is a schematic cross sectional view showing a preferred embodiment of an image pickup device according to the invention.

1 denotes an antireflection film; 2 denotes infrared-barriering dielectric multilayer film; 3, 4, 5 denote protective layer; 6 denotes a transparent counter electrode; 7 denotes an electron blocking layer; 8 denotes a p-layer; 9 denotes an n-layer; 10 denotes a hole blocking layer; 11, 12 denote layer containing metallic wirings; 13 denotes a single crystal silicon substrate; 14 denotes a transparent pixel electrode; 15 denotes a plug; 16 denotes a pad; 17 denotes a light shielding film; 18 denotes a connecting electrode; 19 denotes a metallic wiring; 20 denotes a counter electrode pad; 21 denotes an n-layer; 22 denotes a p-layer; 23 denotes an n-layer; 24 denotes a p-layer; 25 denotes an n-layer; 26 denotes a transistor; 27 denotes a signal read-out pad; 101 denotes a p-well layer; 102, 104, 106 are high-concentration impurity regions; 103, 105, 107 are MOS circuits; 108 denotes a gate insulating film; 109, 110 denote insulating films; 111, 114, 116, 119, 121, 124 are transparent electrode films; 112, 117, 122 denote electrodes; 113, 118, 123 denote photoelectric conversion films; 110, 115, 120, 125 denote transparent insulating films; 126 denotes light shielding film; and 150 denotes a semiconductor substrate.

### DETAILED DESCRIPTION OF THE INVENTION

The photoelectric conversion device of the invention has an organic photoelectric conversion film intervening between at least two electrodes, and the organic photoelectric conversion film contains a positive hole transporting photoelectric conversion film and an electron transporting photoelectric conversion film. The positive hole transporting photoelectric conversion film and the electron transporting photoelectric conversion film each has absorption in a visible range, and a difference in wavelength between longer wavelength ends of absorption of the positive hole transporting photoelectric conversion film and the electron transporting photoelectric conversion film is 50 nm or less. The difference in wavelength between longer wavelength ends of absorption of the positive hole transporting photoelectric conversion film and the electron transporting photoelectric conversion film is preferably 0 to 40 nm, and more preferably from 0 to 30 nm. In the absorption spectra of the two photoelectric conversion films, it is preferred that the maximum value on the longer wavelength side of one of the spectra has an intensity of from 10 to 90%, more preferably from 20 to 80%, and particularly preferably from 30 to 70%, of the intensity of the maximum value on the longer wavelength side of the other. It has been found that according to the configuration, in which the positive hole transporting photoelectric conversion film and the electron transporting photoelectric conversion film emit light in the same wavelength range, whereby an image pickup device having a high quantum efficiency.

[Organic p-Type and n-Type Compounds]

An organic p-type semiconductor (compound) constituting the positive hole transporting photoelectric conversion film and an organic n-type semiconductor (compound) constituting the electron transporting photoelectric conversion film are selected to provide the characteristic features of the invention while they are not particularly limited. The organic semiconductor (compound) may not have absorption in an ultraviolet range, a visible range and an infrared range, but it is preferably a compound having absorption in a visible range (i.e., an organic colorant). A colorless p-type or n-type compound may be endowed with absorption in a visible range by adding anorganic colorant to the colorless compound.

The organic p-type semiconductor (compound) is a donative organic semiconductor (compound), which means an organic compound having such a nature that it tends to donate electrons, which is mainly represented by a positive hole transporting organic compound. More specifically, upon making two organic materials in contact to each other, the organic p-type compound is such an organic compound that has a smaller ionization potential. Therefore, any organic compound having an electron donative nature can be used as the donative organic compound. Examples thereof include a triphenylamine compound, a benzidine compound, a pyrazoline compound, a styrylamine compound, a hydrazone compound, a triphenylmethane compound, a carbazole compound, a polysilane compound, a thiophene compound, a phthalocyanine compound, a cyanine compound, a merocyanine compound, an oxonol compound, a polyamine compound, an indole compound, a pyrrole compound, a pyrazole compound, a polyarylene compound, a condensed aromatic carbocyclic compound (such as a naphthalene derivative, an anthracene derivative, a phenanthrene derivative, a tetracene derivative, a pyrene derivative, a perylene derivative and a foluorantene derivative), and a metallic complex having a nitrogen-containing heterocyclic compound as a ligand. The donative organic semiconductor is not limited to these examples and may be such anorganic compound that has a smaller ionization potential than that of the organic compound used as then-type (acceptive) compound, as described herein above.

The organic n-type semiconductor (compound) is an acceptive organic semiconductor (compound), which means an organic compound having such a nature that it tends to accept electrons, which is mainly represented by an electron transporting organic compound. More specifically, upon making two organic materials in contact to each other, the organic n-type compound is such an organic compound that has a larger electron affinity. Therefore, any organic compound having an electron acceptive nature can be used as the acceptive organic compound. Examples thereof include a condensed aromatic carbocyclic compound (such as a naphthalene derivative, an anthracene derivative, a phenanthrene derivative, a tetracene derivative, a pyrene derivative, a perylene derivative and a foluorantene derivative), a 5- to 7-membered heterocyclic compound containing a nitrogen atom, an oxygen atom or a sulfur atom (such as pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, betnzothiazole, carbazole, purine, triazolopyridazine, triazolopyrimidine, tetrazaindene, oxadiazole, imidazopyridine, pyralidine, pyrrolopyridine, thiadizolopyridine, dibenzazepine and tribenzazepine), a polyarylene compound, a fluorene compound, acyclopentadiene compound, a silyl compound, and a metallic complex having a nitrogen-containing heterocyclic compound as a ligand. The acceptive organic semiconductor is not limited to these examples and may be such an organic compound that has a larger electron affinity than that of the organic compound used as the donative compound, as described hereinabove.

The p-type organic colorant and the n-type organic colorant may be selected from any compound, and preferred examples thereof include a cyanine colorant, a styryl colorant, a hemicyanine colorant, a merocyanine colorant (including zero-methine merocyanine (simple merocyanine)), a trinuculeus merocyanine colorant, a tetranuculeus merocyanine colorant, a rhodacyanine colorant, a complex cyanine colorant, a complex merocyanine colorant, an allopolar colorant, anoxonol colorant, a hemioxonol colorant, a squalirium colorant, a croconium colorant, an azamethine colorant, a coumarin colorant, an arylidene colorant, an anthraquinone colorant, a triphenylmethane colorant, an azo colorant, an azomethine colorant, a spiro compound, a metallocene colorant, a fluorenone colorant, a fulgide colorant, a perylene colorant, a phenazine colorant, a phenothiazine colorant, a quinone colorant, an indigo colorant, a diphenylmethane colorant, a polyene colorant, an acridine colorant, an acridinone colorant, a diphenylamine colorant, a quinacridone colorant, a quinophthalone colorant, a phenoxadine colorant, a phthaloperylene colorant, a diketopyrrolopyrrole colorant, a dioxane colorant, a porphyrin colorant, a chlorophyll colorant, a phthalocyanine colorant, a metallic complex colorant, and a condensed aromatic carbocyclic compound (such as a naphthalene derivative, an anthracene derivative, a phenanthrene derivative, a tetracene derivative, a pyrene derivative, a perylene derivative and a foluorantene derivative)

A film formed with the p-type organic colorant or the n-type organic colorant may be in either an amorphous state or a crystalline state, and is preferably in a crystalline state upon forming a photoelectric conversion film. Examples of the film in a crystalline state include those formed with a pigment that has crystallinity among the aforementioned p-type and n-type colorants.

The layer containing the organic compound is formed by a dry film forming method or a wet film forming method. Specific examples of the dry film forming method include a physical vapor phase growing method, such as a vacuum deposition method, an ion plating method and MBE method, and a CVD method, such as a plasma polymerization method. Examples of the wet film forming method include a casting method, a spin coating method, a dipping method and an LB method.

In the case where a polymer compound is used as at least one of the p-type semiconductor (compound) or the n-type semiconductor (compound), it is preferably formed into a film by the wet film forming method, by which the film can be easily formed. In the case where the dry film forming method, such as vapor deposition, is applied thereto, a polymer is difficult to use due to the possibility of decomposing the polymer, but an oligomer can be preferably used instead. In the case where a low molecular weight compound is used, the film is preferably formed by the dry film forming method, such as a co-deposition method.

[Half-Value Width]

In order to provide the photoelectric conversion device of the invention with good color reproducibility through spectral capability to blue, green and red colors, the film absorption spectrum of the organic photoelectric conversion film preferably has an absorption maximum on the longest wavelength side (visible region) having a half-value width of from 50 to 150 nm, more preferably from 50 to 120 nm, and particularly preferably from 50 to 100 nm.

[Wavelength Dependency of Absorption Strength]

It is preferred that the organic photoelectric conversion film has a film absorption spectrum in at least one range of blue light, green light and red light in a wavelength range of 400 nm or more, and the absorption spectrum in the range has an absorption maximum having a maximum value of three times or more, preferably five times or more, and particularly preferably ten times or more, a maximum value of an absorption maximum in a wavelength range outside the range. The absorption spectrum preferably has a maximum value at a wavelength of from 400 to 500 nm, from 500 to 600 nm, or from 600 to 700 nm, more preferably from 420 to 480 nm, from 520 to 580 nm, or from 620 to 680 nm, and particularly preferably from 430 to 470 nm, from 530 to 570 nm or from 620 to 670 nm.

[Spectral Sensitivity]

The photoelectric conversion spectrum, which indicates the spectral sensitivity, preferably has a maximum value at a wavelength of from 420 to 480 nm, from 510 to 570 nm, or from 600 to 660 nm, and more preferably from 430 to 470 nm, from 520 to 560 nm, or from 610 to 650 nm. It has also been found that the colorant compound in the invention has a preferred spectral absorption wavelength and a preferred spectral sensitivity range.

In a device according to the invention that satisfies the aforementioned requirements, a BGR photoelectric conversion film, i.e., a laminated photoelectric conversion film having three layers including a blue photoelectric conversion film, a green photoelectric conversion film and a red photoelectric conversion film, with good color reproducibility can be preferably used to realize good color reproducibility.

[Ionization Potential (Ip) and Electron Affinity (Ea)]

It has also found that the efficiency can be improved in the case where the ionization potential (Ip) and the electron affinity (Ea) of the photoelectric conversion film of the photoelectric conversion device having the BGR spectral capability satisfy the following conditions. That is, the ionization potential (Ip₁) and the electron affinity (Ea₁) of the positive hole transporting photoelectric conversion film and the ionization potential (Ip₂) and the electron affinity (Ea₂) of the electron transporting photoelectric conversion film preferably satisfy relationships Ip₁<Ip₂ and Ea₁<Ea₂,

[Application of Charge Transporting Layer]

The device of the invention may have a charge transporting layer in addition to the photoelectric conversion layer between the two electrodes, and the charge transporting layer may have either a positive hole transporting nature or an electron transporting nature. Examples of the positive hole transporting material include those exemplified for the organic p-type semiconductor (compound), and a triarylamine compound and a phthalocyanine compound are particularly preferred.

Examples of the electron transporting material include those exemplified for the organic n-type semiconductor (compound), and a 5- to 7-membered heterocyclic compound containing a nitrogen atom, an oxygen atom or a sulfur atom is preferred, with a phenanthroline derivative, represented by BCP (bathocuproin), and a compound represented by the general formula (I) being particularly preferred.

A longer wavelength end of an absorption spectrum of the charge transporting layer is preferably at a shorter wavelength than a longer wavelength end of an absorption spectrum of the photoelectric conversion film, more preferably shorter by 50 nm or more, further preferably shorter by 100 nm or more and particularly preferably shorter by 150 nm or more.

[Electron Transporting Material]

In the photoelectric conversion device of the invention, the organic material having an electron transporting nature (n-type compound) preferably has an ionization potential of more than 6.0 eV, and is preferably represented by the general formula (I).

The compound represented by the general formula (I) will be described. A represents a heterocyclic ring containing two or more aromatic heterocyclic rings condensed to each other, and plural heterocyclic rings represented by A may be the same as or different from each other. The heterocyclic group represented by A is preferably a heterocyclic group formed by condensing 5- or 6-membered aromatic heterocyclic rings, and more preferably formed by condensing from 2 to 6, further preferably from 2 or 3, and particularly preferably 2, aromatic heterocyclic rings. Preferred examples of the hetero atom include N, O, S, Se, and Te atoms, more preferably N, O and S atoms, and further preferably a N atom. Specific examples of the aromatic heterocyclic ring constituting the heterocyclic group represented by A include furan, thiophene, pyrrole, imidazole, pyrazole, pyridine, pyrazine, pyrimidine, pyridazine, thiazole, oxazole, isothiazole, isoxazole, thiadiazole, oxadiazole, triazole, selenazole and tellurazole, preferably imidazole, pyrazole, pyridine, pyrazine, pyrimidine, pyridazine, thiazole and oxazole, and more preferably imidazole, thiazole, oxazole, pyridine, pyrazine, pyrimidine and pyridazine.

Specific examples of the condensed ring represented by A include indoridine, purine, pteridine, carboline, pyrroloimidazole, pyrrolotriazole, pyrazoimidazole, pyrazolotriazole, pyrazolopyrimidine, pyrazolotriazine, triazolopyridine, tetrazaindene, pyrroloimidazole, pyrrolotriazole, imidazoimidazole, imidazopyridine, imidazopyrazine, imidazopyrimidine, imidazopyridazine, oxazolopyridine, oxazolopyrazine, oxazolopyrimidine, oxazo-lopyridazine, thiazolopyridine, thiazolopyrazine, thiazolopyrimidine, thiazolopyridazine, pyridinopyrazine, pyrazinopyrazine, pyrazinopyridazine, naphthylidine and imidazotriazine, preferably imidazopyridine, imidazopyrazine, imidazopyrimidine, imidazopyridazine, oxazolopyridine, oxazolopyrazine, oxazolopyrimidine, oxazolopyridazine, thiazolopyridine, thiazolopyrazine, thiazolopyrimidine, thiazolopyridazine, pyridinopyrazine and pyrazinopyrazine, further preferably imidazopyridine, oxazolopyridine, thiazolopyridine, pyridinopyrazine and pyrazinopyrazine, and particularly preferably imidazopyridine.

The heterocyclic group represented by A may be further condensed with another ring and may have a substituent.

Preferred specific examples of the substituent on the heterocyclic group represented by A include an alkyl group, an alkenyl group, an alkenyl group, an alkynyl group, an aryl group, an amino group, an alkoxy group, an aryloxy group, an acyl group, an alkoxycarbonyl group, an aryloxycarbonyl group, an acyloxy group, an acylamino group, an alkoxycarbonylamino group, an aryloxycarbonylamino group, a sufonylamino group, a sulfamoyl group, a carbamoyl group, an alkylthio group, an arylthio group, a sulfonyl group, a halogen atom, a cyano group and a heterocyclic group, more preferably an alkyl group, an alkenyl group, an aryl group, an alkoxy group, an aryloxy group, a halogen atom, a cyano group and a heterocyclic group, further preferably an alkyl group, an aryl group, an alkoxy group, an aryloxy group and an aromatic heterocyclic group, and particularly preferably an alkyl group, an aryl group, an alkoxy group and an aromatic heterocyclic group.
m represents an integer of 2 or more, preferably from 2 to 8, more preferably from 2 to 6, further preferably from 2 to 4, particularly preferably 2 or 3, and most preferably 3.

L represents a linking group. Preferred examples of the linking group represented by L include a single bond and a linking group containing C, N, O, S, Si and Ge, more preferably a single bond, an alkylene group, an alkenylene group, an alkynylene group, an arylene group, a divalent heterocyclic ring (preferably an aromatic heterocyclic ring, and more preferably an aromatic heterocyclic ring formed with an azole ring, a thiophene ring and a furan ring), N, and a group formed of these groups or atoms, and further preferably an arylene group, a divalent aromatic heterocyclic ring, N, and a group formed of these groups or atoms. The linking group represented by L may have a substituent, and examples of the substituent include those exemplified as the substituent on the heterocyclic group represented by A.

Specific examples of the linking group represented by L include a single bond and those disclosed in paragraphs 0037 to 0040 of Japanese Patent Application No. 2004-082002.

The compound represented by the general formula (I) is a compound represented by the general formula (III).

The general formula (III) will be described. m and L have the same meanings as those in the general formula (I), and the preferred ranges thereof are also the same. X represents O, S, Se, Te or N—R, and R represents a hydrogen atom, an aliphatic hydrocarbon group, an aryl group or a heterocyclic group. Q₃ represents an atomic group forming an aromatic heterocyclic ring.

Preferred examples of the aliphatic hydrocarbon group represented by R include an alkyl group (preferably having from 1 to 20 carbon atoms, more preferably from 1 to 12 carbon atoms, and particularly preferably from 1 to 8 carbon atoms, such as methyl, ethyl, iso-propyl, tert-butyl, n-octyl, n-decyl, n-hexadecyl, cyclopropyl, cyclopentyl and cyclohexyl), an alkenyl group (preferably having from 2 to 20 carbon atoms, more preferably from 2 to 12 carbon atoms, and particularly preferably from 2 to 8 carbon atoms, such as vinyl, allyl, 2-butenyl and 3-pentenyl) and an alkynyl group (preferably having from 2 to 20 carbon atoms, more preferably from 2 to 12 carbon atoms, and particularly preferably from 2 to 8 carbon atoms, such as propargyl and 3-pentynyl), and more preferably an alkyl group and an alkenyl group.

The aryl group represented by R preferably has from 6 to 30 carbon atoms, more preferably from 6 to 20 carbon atoms, and particularly preferably from 6 to 12 carbon atoms, and examples thereof include phenyl, 2-methylphenyl, 3-methylphenyl, 4-methylphenyl, 4-methoxyphenyl, 3-trifluoromethylphenyl, pentafluorophenyl, 2-biphenylyl, 3-biphenylyl, 4-biphenylyl, 1-naphthyl, 2-naphthyl and 1-pyrenyl.

The heterocyclic group represented by R is preferably a monocyclic or condensed ring heterocyclic group (preferably a heterocyclic group having from 1 to 20 carbon atoms, more preferably from 1 to 12 carbon atoms, and further preferably from 2 to 10 carbon atoms), and more preferably an aromatic heterocyclic group containing at least one of a nitrogen atom, an oxygen atom, a sulfur atom and a selenium atom. Specific examples of the heterocyclic group represented by R include pyrrolidine, piperidine, pyrrole, furan, thiophene, imidazoline, imidazole, benzimidazole, naphthoimidazole, thiazolidine, thiazole, benzthiazole, naphthothiazole, isothiazole, oxazoline, oxazole, benzoxazole, naphthoxazole, isoxazole, selenazole, benzselenazole, naphthoselenazole, pyridine, quinoline, isoquinoline, indole, indolenine, pyrazole, pyrazine, pyrimidine, pyridazine, triazine, indazole, purine, phthalazine, naphthylidine, quinoxaline, quinazoline, cinnoline, pteridine, phenanthridine, pteridine, phenanthroline and tetrazaindene, preferably furan, thiophene, pyridine, quinoline, pyrazine, pyrimidine, pyridazine, triazine, phthalazine, naphthylidine, quinoxaline and quinazoline, more preferably furan, thiophene, pyridine and quinoline, and particularly preferably quinoline.

The aliphatic hydrocarbon group, the aryl group and the heterocyclic group represented by R may have a substituent. Examples of the substituent include those exemplified as the substituent on the heterocyclic group represented by A, and the preferred examples thereof are the same. R preferably represents an alkyl group, an aryl group or an aromatic heterocyclic group, preferably an aryl group or an aromatic heterocyclic group, and further preferably an aryl group or an aromatic azole group.

X preferably represents O, S or N—R, more preferably O or N—R, further preferably N—R, and particularly preferably N—Ar, wherein Ar represents an aryl group or an aromatic azole group, more preferably an aryl group having from 6 to 30 carbon atoms or an aromatic azole group having from 2 to 30 carbon atoms, further preferably an aryl group having from 6 to 20 carbon atoms or an aromatic azole group having from 2 to 16 carbon atoms, and particularly preferably an aryl group having from 6 to 12 carbon atoms or an azole group having from 2 to 10 carbon atoms.

Q₃ represents an atomic group forming an aromatic heterocyclic ring. The aromatic heterocyclic ring formed with Q₃ is preferably a 5- or 6-membered aromatic heterocyclic ring, more preferably a 5- or 6-membered nitrogen-containing aromatic heterocyclic ring, and further preferably a 6-membered nitrogen-containing aromatic heterocyclic ring. Specific examples of the aromatic heterocyclic ring formed with Q₃ include furan, thiophene, pyran, pyrrole, imidazole, pyrazole, pyridine, pyrazine, pyrimidine, pyridazine, thiazole, oxazole, isothiazole, isoxazole, thiadiazole, oxadiazole, triazole, selenazole and tellurazole, preferably pyridine, pyrazine, pyrimidine and pyridazine, more preferably pyridine and pyrazine, and further preferably pyridine. The heterocyclic group represented by Q₃ may be further condensed with an another ring and may have a substituent. Examples of the substituent include those exemplified as the substituent on the heterocyclic group represented by A, and preferred examples thereof are the same.

Specific examples of the compound represented by the general formula (I) (including the compound represented by the general formula (III)) are shown below, but the invention is not limited thereto. Other examples thereof include the compounds disclosed in Japanese Patent Application No. 2004-082002 as Compound Nos. 1 to 20 in paragraphs 0086 to 0090 and Nos. 27 to 118 in paragraphs 0093 to 0121.

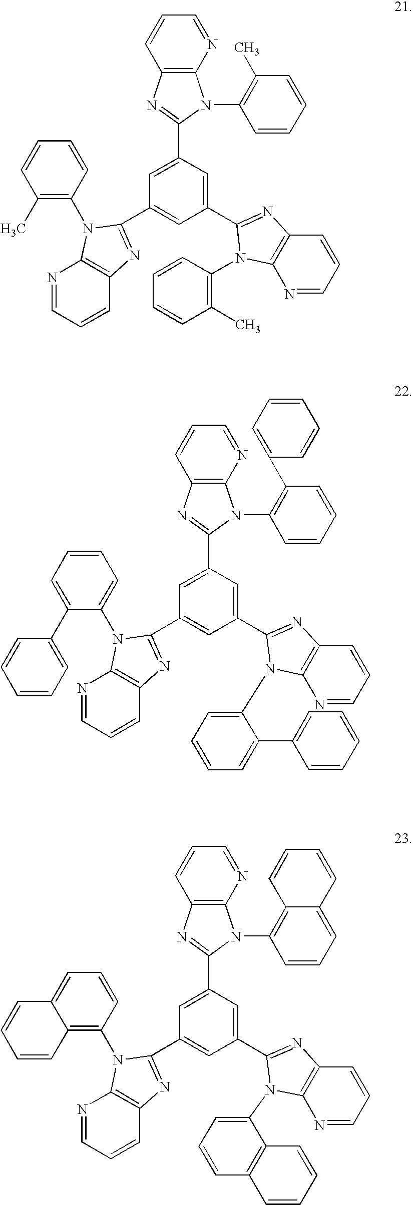

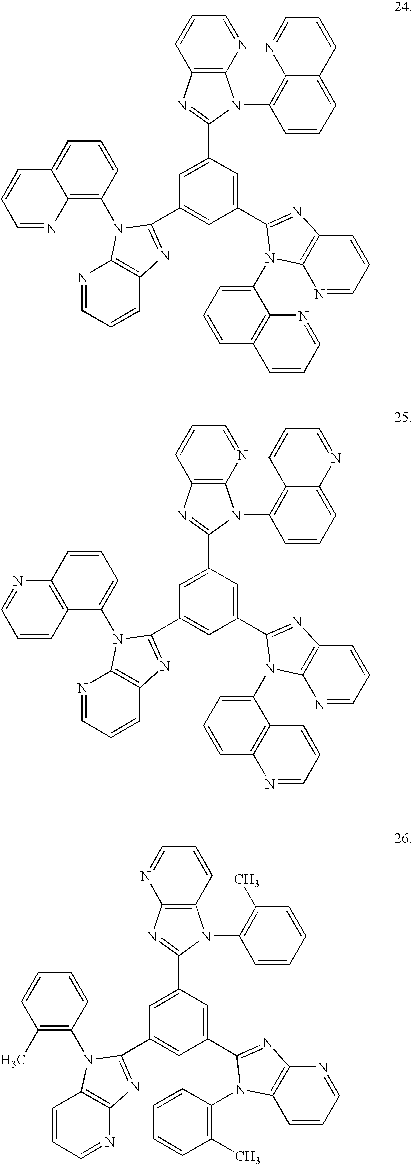

Detailed explanations and preferred ranges of the organic materials having an electron transporting nature are described in detail in Japanese Patent Application No. 2004-082002.

It has been found that the use of the electron transporting organic material provides a photoelectric conversion film having an extremely high photoelectric conversion efficiency and improved durability.

[Electrode]

A positive electrode is defined as such an electrode that takes out positive holes from the positive hole transporting photoelectric conversion layer or the positive hole transporting layer, and can be formed with a metal, an alloy, a metallic oxide, an electroconductive compound, or a mixture thereof, and preferably with a material having a work function of 4 eV or more. Specific examples thereof include an electroconductive metallic oxide, such as tin oxide, zinc oxide, indium oxide and indium tin oxide (ITO), a metal, such as gold, silver, chromium and nickel, a mixture or a laminated material of a metal and an electroconductive metallic oxide, an inorganic electroconductive substance, such as copper iodide and copper sulfide, an organic electroconductive material, such as polyaniline, polythiophene and polypyrrole, a silicone compound, and a laminated body of these materials with ITO, and preferably an electroconductive metallic oxide, and in particular, ITO is preferred from the standpoint productivity, high electroconductivity and transparency. The thickness of the positive electrode can be appropriately selected depending on the material, and in general, it is preferably from 10 nm to 5 μm, more preferably from 50 nm to 1 μm, and further preferably from 100 to 500 nm.

The positive electrode is generally formed as a layer on such a substrate as soda lime glass, non-alkali glass and a transparent resin substrate. In the case where glass is used, non-alkali glass is preferably used in order to suppress ions from being eluted from the glass. In the case where soda lime glass is used, it is preferred that a barrier coating, such as silica, is formed thereon. The thickness of the substrate is not particularly limited as far as it has sufficient mechanical strength, and in the case where glass is used, the thickness is generally 0.2 mm or more, and preferably 0.7 mm or more. The production method of the positive electrode may be variously selected depending on the material therefor, and in the case of ITO for example, the layer can be formed by an electron beam method, a sputtering method, a resistance heating vapor deposition method, a chemical reaction method (such as a sol-gel method), and a method of coating a dispersion of indium tin oxide. The positive electrode can be improved in luminescent efficiency through reduction of the driving voltage of the device by cleaning the positive electrode. In the case of ITO, for example, the positive electrode can be effectively cleaned by a UV-ozone treatment or a plasma treatment.

A negative electrode is to take out electrons from the electron transporting photoelectric conversion layer or the electron transporting layer, and the material therefor is selected in consideration of adhesion to the adjacent layer, such as the electron transporting photoelectric conversion layer and the electron transporting layer, the electron affinity, the ionization potential, and the stability. Examples of the material for the negative electrode include a metal, an alloy, a metallic halide, a metallic oxide, an electroconductive compound, ITO, IZO, and a mixture thereof, and specific examples thereof include an alkali metal (e.g., Li, Na and K) and a fluoride or an oxide thereof, an alkaline earth metal (e.g., Mg and Ca) and a fluoride or an oxide thereof, gold, silver, lead, aluminum, a sodium-potassium alloy or a mixed metal thereof, a lithium-aluminum alloy or a mixed metal thereof, a magnesium-silver alloy or a mixed metal thereof, and a rare earth metal, such as indium and ytterbium, preferably a material having a work function of 4 eV or less, and more preferably aluminum, silver, gold and a mixed metal thereof. The negative electrode may have a laminated structure of the aforementioned compounds and mixtures, as well as a single layer structure of the aforementioned compound or mixture. Examples of the laminated structure include laminated structures of aluminum and lithium fluoride, and aluminum and lithium oxide. The thickness of the negative electrode can be appropriately selected depending on the material, and in general, it is preferably from 10 nm to 5 μm, more preferably from 50 nm to 1 μm, and further preferably from 100 nm to 1 μm.

The negative electrode can be produced by an electron beam method, a sputtering method, a resistance heating vapor deposition method and a coating method, and a single component of a metal can be solely vapor-deposited, or plural components can be simultaneously vapor-deposited. Furthermore, plural metals can be simultaneously vapor-deposited to form an alloy electrode, and an alloy having been prepared may be vapor-deposited. The sheet resistance of the positive electrode and the negative electrode is preferably as low as possible, specifically it is preferably several hundreds Ω per square.

[Generic Requirements]

It is preferred in the invention that the photoelectric conversion device has two or more layers of the photoelectric conversion film laminated, more preferably three or four layers thereof laminated, and particularly preferably three layers thereof laminated.

In the invention, the photoelectric conversion device can be preferably used as an image pickup device.

In the invention, the photoelectric conversion film, the photoelectric conversion device and the image pickup device are preferably applied with a voltage.

It is preferred in the photoelectric conversion device of the invention that a p-type semiconductor layer and an n-type semiconductor layer form a laminated structure between a pair of electrodes. It is more preferred that at least one of the p-type and n-type semiconductor layers contain an organic compound, and it is further preferred that both the p-type and the n-type semiconductor layers contain an organic compound.

[Application of Voltage]

It is preferred that the photoelectric conversion film of the invention is applied with a voltage since the photoelectric conversion efficiency is improved. The voltage applied is not particularly limited, and the necessary voltage varies depending on the thickness of the photoelectric conversion film. That is, the photoelectric conversion efficiency is improved when the electric field applied is increased, and the electric field is increased by decreasing the thickness oaf the photoelectric conversion film with the constant applied voltage. Therefore, the applied voltage may be relatively small when the thickness of the photoelectric conversion film is small. The electric field applied to the photoelectric conversion film is preferably 10 V/m or more, more preferably 10×10³ V/m or more, more preferably 1×10⁵ V/m or more, particularly preferably 1×10⁶ V/m or more, and most preferably 1×10⁷ V/m or more. The upper limit of the electric field is not particularly limited, and is preferably 1×10¹² V/m or less, and more preferably 1×10⁹ V/m or less, since an electric current flows in a dark space when the electric field is too large.

[Bulk Hetero Junction Structure]

In the invention, the photoelectric conversion film (photosensitive layer) preferably has such a structure that the p-type semiconductor layer and the n-type semiconductor layer intervene between a pair of electrodes wherein at least one of the semiconductor layers contain an organic semiconductor, and a bulk hetero junction structure layer containing the p-type semiconductor and the n-type semiconductor intervenes between the semiconductor layers. In the case where the photoelectric conversion film has the structure, the organic layer has the bulk hetero junction structure, whereby such a disadvantage that the carrier diffusion length of the organic layer is short can be avoided to improve the photoelectric conversion efficiency.

The bulk hetero junction structure is described in detail in Japanese Patent Application No. 2004-080639.

[Tandem Structure]

In the invention, the photoelectric conversion film (photosensitive layer) preferably has such a structure that two or more repeated structures (tandem structures) of a pn-junction layer formed by the p-type semiconductor layer and the n-type semiconductor layer intervening between a pair of electrodes, and more preferably such a structure that a thin layer of an electroconductive material intervenes between the repeated structures. The number of the repeated structures (tandem structures) of the pn-junction layer is not limited, and is preferably from 2 to 50, more preferably from 2 to 30, and particularly preferably from 2 to 10, for improving the photoelectric conversion efficiency. The electroconductive material is preferably silver or gold, and most preferably silver.

In the invention, the semiconductor having the tandem structure may be an inorganic material, but is preferably an organic semiconductor, and more preferably an organic colorant.

The tandem structure is described in detail in Japanese Patent Application No. 2004-079930.

[Orientation]

In the case where the image pickup device of the invention has a photoelectric conversion film having a p-type semiconductor layer and an n-type semiconductor layer (preferably a mixed and dispersed layer (having the bulk hetero structure)), the photoelectric conversion film preferably has such a structure that at least one of the p-type semiconductor and the n-type semiconductor contains an organic compound having been controlled in orientation in one direction, and more preferably both the n-type semiconductor and the p-type semiconductor contain an organic compound having been oriented (or an organic compound capable of being oriented).

The organic compound used in the organic layer of the photoelectric conversion film preferably has π-conjugated electrons, and it is preferred that the π-electron plane is not perpendicular to the substrate (electrode substrate) but is oriented in such a direction that is as close as possible to the angle in parallel to the substrate. The angle of the π-electron plane to the substrate is preferably from 0 to 80°, more preferably from 0 to 60°, further preferably from 0 to 40°, still further preferably from 0 to 20°, particularly preferably from 0 to 10°, and most preferably 0° (i.e., in parallel to the substrate).

The layer of an organic compound having been controlled in orientation may be contained as at least a part of the whole organic layer, and is preferably contained in a proportion of 10% or more, more preferably 30% or more, further preferably 50% or more, still further preferably 70% or more, particularly preferably 90% or more, and most preferably 100%, of the whole organic layer.

According to the constitution, the organic compound in the organic layer of the photoelectric conversion film is controlled in orientation, whereby such a disadvantage that the carrier diffusion length of the organic layer is short can be avoided to improve the photoelectric conversion efficiency.

In the case where the organic compound in the invention has been controlled in orientation, it is more preferred that the hetero junction plane (for example, the pn-junction plane) is not in parallel to the substrate. It is preferred that the hetero junction plane is not in parallel to the substrate (electrode substrate) but is oriented in such a direction that is as close as possible to the angle perpendicular to the substrate. The angle of the hetero junction plane to the substrate is preferably from 10 to 90°, more preferably from 30 to 90°, further preferably from 50 to 90°, still further preferably from 70 to 90°, particularly preferably from 80 to 90°, and most preferably 90° (i.e., perpendicular to the substrate).

The layer of an organic compound having been controlled in hetero junction plane may be contained as at least a part of the whole organic layer, and is preferably contained in a proportion of 10% or more, more preferably 30% or more, further preferably 50% or more, still further preferably 70% or more, particularly preferably 90% or more, and most preferably 100%, of the whole organic layer. According to the constitution, the area of the hetero junction plane in the organic layer is increased, whereby the amount of carriers, such as electrons, holes and electron-hole pairs, is increased to improve the photoelectric conversion efficiency.

The photoelectric conversion film having been controlled in orientation of both the hetero junction plane and the n-electron plane can provide a particularly improved photoelectric conversion efficiency.

The aforementioned constitutions are described in detail in Japanese Patent Application No. 2004-079931.

[Thickness of Organic Colorant Layer]

In the case where the photoelectric conversion film of the invention is used as a color image pickup device (image sensor), the B, G and R layers of the organic colorant layers preferably have a light-absorbing ratio of 50% or more, more preferably 70% or more, particularly preferably 90% (absorbance of 1) or more, and most preferably 99% or more, for improving the photoelectric conversion efficiency and for improving the color separation without irradiating the lower layer with unnecessary light. Therefore, the thickness of the organic colorant layer is preferably as large as possible from the standpoint of light absorption, but in consideration of such a proportion that does not contribute to charge separation, the thickness of the organic colorant layer in the invention is preferably from 30 to 300 nm, more preferably from 50 to 150 nm, and particularly preferably from 80 to 130 nm.

[BGR Spectral Capability]

In the invention, a BGR photoelectric conversion film, i.e., a laminated photoelectric conversion film having three layers including a blue photoelectric conversion film, a green photoelectric conversion film and a red photoelectric conversion film, with good color reproducibility can be preferably used.

The respective photoelectric conversion films preferably have the aforementioned spectral absorption and/or spectral sensitivity characteristics.

[Laminated Structure]

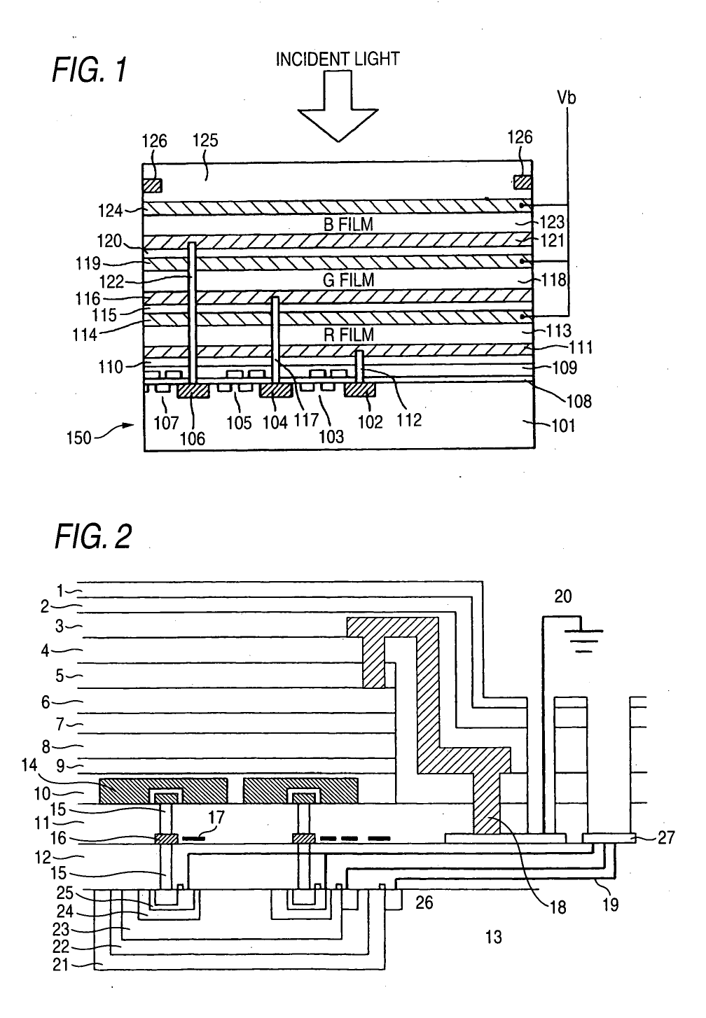

It is preferred in the invention that the photoelectric conversion device has at least two photoelectric conversion films laminated to each other. The laminated image pickup device is not particularly limited, and any type thereof used in this field of art can be applied. It is preferred that the image pickup device has a BGR three-layer laminated structure, and a preferred example of the BGR three-layer laminated structure is shown in FIG. 1.

The solid image pickup device according to the invention has, for example, a photoelectric conversion film according to this embodiment. The solid image pickup device shown in FIG. 1 has a laminated photoelectric conversion film on a scanning circuit. The scanning circuit may have such a structure that MOS transistors for each pixels are formed on a semiconductor substrate, or such a structure that has a CCD as an image pickup device.

In the case of the solid image pickup device using MOS transistors, charge is formed in the photoelectric conversion film by incident light passing through the electrode, and the charge moves within the photoelectric conversion film to the electrode through an electric field between the electrodes generated by applying a voltage to the electrodes and further moves to the charge accumulating part of the MOS transistor, whereby the charge is accumulated in the charge accumulating part. The charge thus accumulated in the charge accumulating part moves to the charge read-out part through switching of the MOS transistor, and is output as an electric signal. Accordingly, a full color image signal is input to the solid image pickup device including a signal processing part.

As the laminated image pickup device, a solid color image pickup device, which is represented by those disclosed in FIG. 2 of JP-A-58-103165 and FIG. 2 of JP-A-58-103166, can be applied.

As the production process of the laminated image pickup device, preferably the three-layer laminated image pickup device, the process disclosed in JP-A-2002-83946, FIGS. 7 to 23 and paragraphs 0026 to 0038.

(Photoelectric Conversion Device)

A preferred embodiment of the photoelectric conversion device according to the invention will be described.

The photoelectric conversion device of the invention contains an electromagnetic wave absorbing and photoelectric conversion part, and a part for accumulating, transporting and reading out the charge generated through photoelectric conversion.

The electromagnetic wave absorbing and photoelectric conversion part in the invention has a laminated structure of at least two layers capable of attaining photoelectric conversion of blue light, green light and red light, respectively. The blue light absorbing layer (B) can absorb light having a wavelength of from 400 to 500 nm, and the absorbance thereof at the peak wavelength within the wavelength range is preferably 50% or more. The green light absorbing layer (G) can absorb light having a wavelength of from 500 to 600 nm, and the absorbance thereof at the peak wavelength within the wavelength range is preferably 50% or more. The red light absorbing layer (R) can absorb light having a wavelength of from 600 to 700 nm, and the absorbance thereof at the peak wavelength within the wavelength range is preferably 50% or more. The order of the layers may be arbitrarily selected, and in the case of the three-layer laminated structure, the order may be either BGR, BRG, GBR, GRB, RBG or RGB, from the upper layer. It is preferred that the G layer is the uppermost layer. In the case of the two-layer laminated structure, it is preferred that the B and G layers are present in the same plane of the lower layer when the R layer is the upper layer, the G and R layers are present in the same plane of the lower layer when the B layer is the upper layer, or the B and R layers are present in the same plane of the lower layer when the G layer is the upper layer. It is preferred that the G layer is the upper layer, and the B and R layers are present in the same plane of the lower layer. In the case where two light absorbing layers are present in the same plane of the lower layer, it is preferred to provide a filter layer having, for example, a mosaic pattern, above the upper layer or between the upper layer and the lower layer. In some cases, additional layers including the fourth layer or further layers may be provided as a new layer or in the same plane of the existing layer.

The charge accumulating, transporting and reading out part in the invention is provided under the electromagnetic wave absorbing and photoelectric conversion part. It is preferred that the electromagnetic wave absorbing and photoelectric conversion part as the lower layer also functions as the charge accumulating, transporting and reading out part.

The electromagnetic wave absorbing and photoelectric conversion part in the invention is constituted by an organic layer, an inorganic layer or a mixture of an organic layer and an inorganic layer. The B, G and R layers may be formed with an organic layer, or the B, G and R layers may be formed with an inorganic layer. A mixture of an organic layer and an inorganic layer is preferably used. In this case, one or two inorganic layers are basically used when one organic layer is used, and one inorganic layer is basically used when two organic layers are used. In the case where one organic layer and one inorganic layer are used, the inorganic layer forms electromagnetic wave absorbing and photoelectric conversion parts for two or more colors in the same plane. It is preferred that an organic G layer is formed as an upper layer, and an inorganic B layer and an inorganic R layer are formed in this order from the above as lower layers. In some cases, additional layers including the fourth layer or further layers may be provided as a new layer or in the same plane of the existing layer. In the case where the B, G and R layers are formed as organic layers, the charge accumulating, transporting and reading out part is provided thereunder. In the case where the electromagnetic wave absorbing and photoelectric conversion part is provided as an inorganic layer, the inorganic layer also functions as the charge accumulating, transporting and reading out part.

Among the aforementioned devices, one of particularly preferred embodiments of the invention is as follows.

A device has at least two electromagnetic wave absorbing and photoelectric conversion parts, in which at least one of the parts is the device (image pickup device) of the invention.

It is preferred that the at least two electromagnetic wave absorbing and photoelectric conversion parts have a laminated structure having at least two layers. It is also preferred that the device capable of absorbing green light for photoelectric conversion is formed as an upper layer.

It is particularly preferred that the device has at least three electromagnetic wave absorbing and photoelectric conversion parts, in which at least one of the parts is the device (image pickup device) of the invention.

It is also preferred that the device capable of absorbing green light for photoelectric conversion is formed as an upper layer. Furthermore, it is preferred that at least two electromagnetic wave absorbing and photoelectric conversion parts among the three of them are inorganic layer (which are preferably formed in the silicon substrate).

(Preferred Photoelectric Conversion Device of the Invention)

A preferred photoelectric conversion device of the invention will be described with reference to FIG. 2. Numeral 13 denotes a silicon single crystal substrate, which also functions as electromagnetic wave absorbing and photoelectric conversion parts and parts for accumulating, transporting and reading out the charge generated through photoelectric conversion for blue light and red light. In general, a p-type silicon substrate is used as the substrate 13. Numerals 21, 22 and 23 denote an n-layer, a p-layer and an n-layer, respectively, formed in the silicon substrate. The n-layer 21 is a part for accumulating signal charge of red light, in which signal charge of red light formed by photoelectric conversion at the pn-junction is accumulated. The charge thus accumulated is connected to a signal read-out pad 27 through a transistor 26 and a metallic wiring 19. The n-layer 23 is a part for accumulating signal charge of blue light, in which signal charge of blue light formed by photoelectric conversion at the pn-junction is accumulated. The charge thus accumulated is connected to a signal read-out pad 27 through a transistor similar to the transistor 26 and a metallic wiring 19. The p-layer, n-layers, transistors and metallic wirings are schematically shown herein, and the structures thereof may be appropriately selected according to those having been described. Blue light and red light are distinguished by the depth in the substrate, and it is important that the pn-junction is formed through appropriate selection of the depth in the substrate and the doped concentration. Numeral 12 denotes a layer containing the metallic wiring and is formed mainly with silicon oxide or silicon nitride. The thickness of the layer 12 is preferably as small as possible, and is generally 5 μm or less, preferably 3 μm or less, and more preferably 2 μm or less. Numeral 11 is a layer formed mainly with silicon oxide or silicon nitride as similar to the layer 12. The layers 11 and 12 are provided with a plug for transporting signal charge of green light to the silicon substrate. The plug is connected between the layers 11 and 12 with a pad 16. The plug is preferably formed mainly with tungsten. The pad is preferably formed mainly with aluminum. A barrier layer is preferably provided including the metallic wirings. The signal charge of green light transported through the plug 15 is accumulated in an n-layer 25 in the silicon substrate. The n-layer 25 is separated from the other by a p-layer 24. The charge thus accumulated is connected to a signal read-out pad 27 through a transistor similar to the transistor 26 and the metallic wiring 19. Alight shielding film 17 is provided in the layer 11 because the pn-junction between the layers 24 and 25 forms noises through photoelectric conversion. The light shielding film is generally formed mainly with tungsten or aluminum. The thickness of the layer 12 is preferably as small as possible, and is generally 3 μm or less, preferably 2 μm or less, and more preferably 1 μm or less. The signal read-out pad 27 is preferably formed separately for blue, green and red signals. The aforementioned constitution can be produced by the known process, i.e., the so-called CMOS process.

The electromagnetic wave absorbing and photoelectric conversion part for green light is denoted by numerals 6, 7, 8, 9, 10 and 14. Numeral 6 and 14 denote transparent electrodes, which correspond to a counter electrode and a pixel electrode, respectively. The pixel electrode 14 is a transparent electrode, and a part of aluminum, molybdenum or the like is necessarily provided thereto, in many cases, for improving electric connection to the plug 15. A bias voltage is applied between the transparent electrodes through a wiring from a connecting electrode 18 and a counter electrode pad 20. Such a structure is preferred that a positive bias voltage with respect to the counter electrode 6 is applied to the pixel electrode 14 to accumulate electrons in the n-layer 25. In this structure, numeral 7 denotes an electron blocking layer, 8 denotes a p-layer, 9 denotes an n-layer, and 10 denotes a hole blocking layer, which show a representative layer structure of the organic layer. The thickness of the organic layer containing the layers 7, 8, 9 and 10 is preferably 0.5 μm or less, more preferably 0.3 μm or less, and particularly preferably 0.2 μm or less, in total. The thickness of the transparent counter electrode 6 and the transparent pixel electrode 14 is preferably 0.2 μm or less. Numerals 3, 4 and 5 denote protective films formed mainly with silicon nitride. The production process of the layers including the organic layer can be simplified by the protective films. These layers can relieve damages of the organic layer upon formation of a resist pattern and etching for forming the connecting electrode 18. In order to avoid formation of a resist pattern and etching, the layers can be produced by using masks. The thickness of the protective films 3 and 4 is preferably 0.5 μm or less as far as the aforementioned requirements.

Numeral 3 denotes a protective film for the connecting electrode 18, 2 denotes an infrared-barriering dielectric multilayer film, and 1 denotes an antireflection film. The thickness of the layers 1, 2 and 3 is preferably 1 μm or less in total.

The photoelectric conversion device shown in FIG. 2 has four green pixels per one blue pixel and one red pixel. The device may have one green pixel per one blue pixel and one red pixel, three green pixels per one blue pixel and one red pixel, or two green pixels per one blue pixel and one red pixel, or may have an arbitrary combination thereof. The invention is not limited to the aforementioned preferred embodiments.

(Electrode)

The electromagnetic wave absorbing and photoelectric conversion part formed with an organic layer of the invention is held between a pair of electrodes, which constitute a pixel electrode and a counter electrode, respectively. It is preferred that the lower electrode constitutes a pixel electrode.

The counter electrode preferably takes out holes from the positive hole transporting photoelectric conversion layer or the positive hole transporting layer, and may be formed with such a material as a metal, an alloy, a metallic oxide, an electroconductive compound and a mixture thereof. The pixel electrode preferably takes out electrons from the electron transporting photoelectric conversion layer or the electron transporting layer, and the material therefor is selected in consideration of adhesion to the adjacent layer, such as the electron transporting photoelectric conversion layer and the electron transporting layer, the electron affinity, the ionization potential, and the stability. Specific examples thereof include an electroconductive metallic oxide, such as tin oxide, zinc oxide, indium oxide and indium tin oxide (ITO), a metal, such as gold, silver, chromium and nickel, a mixture or a laminated material of a metal and an electroconductive metallic oxide, an inorganic electroconductive substance, such as copper iodide and copper sulfide, an organic electroconductive material, such as polyaniline, polythiophene and polypyrrole, a silicone compound, and a laminated body of these materials with ITO, and preferably an electroconductive metallic oxide, and in particular, ITO and IZO are preferred from the standpoint productivity, high electroconductivity and transparency. The thickness of the electrode can be appropriately selected depending on the material, and in general, it is preferably from 10 nm to 1 μm, more preferably from 30 to 500 nm, and further preferably from 50 to 300 nm.

Various production processes can be employed for producing the pixel electrode and the counter electrode depending on the materials therefor, and examples thereof for ITO include an electron beam method, a sputtering method, a resistance heating vapor deposition method, a chemical reaction method (such as a sol-gel method), and a method of coating a dispersion of indium tin oxide. The electrode of ITO can be subjected to a UV-ozone treatment or a plasma treatment.

The transparent electrode in the invention is preferably produced by a plasma-free process. In the case where the transparent electrode is produced by a plasma-free process, plasma can be suppressed from adversely affecting the substrate to improve the photoelectric conversion characteristics. The plasma-free process herein means such a process that no plasma is generated upon forming the transparent electrode film, or plasma reaching the substrate is reduced by taking a distance between the plasma source and the substrate of 2 cm or more, preferably 10 cm or more, and more preferably 20 cm or more.

Examples of such an apparatus for forming a transparent electrode that generates no plasma upon forming the transparent electrode include an electron beam vapor deposition apparatus (EB vapor deposition apparatus) and a pulse laser vapor deposition apparatus. Specific examples of the EB vapor deposition apparatus and the pulse vapor deposition apparatus include those disclosed in Y. Sawada, “Tomei Doudenmaku no Shin-tenkai (New Developments of Transparent Electroconductive Films)”, published by CMC Press (1999), Y. Sawada, “Tomei Doudenmaku no Shin-tenkai II (New Developments of Transparent Electroconductive Films II)”, published by CMC Press (2002), Japan Society for the Promotion of Science, Toumei Doudenmaku no Gijutu (Technologies of Transparent Electroconductive Films)”, published by Ohmsha, Ltd. (1999), and the references noted in these literatures. Herein, a method of forming a transparent electrode by using an EB vapor deposition apparatus is referred to as an EB vapor deposition method, and a method of forming a transparent electrode by using a pulse laser vapor deposition apparatus is referred to as a pulse laser vapor deposition method.

Examples of such an apparatus for forming a transparent electrode that the distance between the plasma source and the substrate is 2 cm or more to suppress the plasma from adversely affecting the substrate (hereinafter, referred to as a plasma-free film forming apparatus) include a counter target sputtering apparatus and an arc plasma vapor deposition method, which are also disclosed in Y. Sawada, “Tomei Doudenmaku no Shin-tenkai (New Developments of Transparent Electroconductive Films)”, published by CMC Press (1999), Y. Sawada, “Tomei Doudenmaku no Shin-tenkai II (New Developments of Transparent Electroconductive Films II)”, published by CMC Press (2002), Japan Society for the Promotion of Science, Toumei Doudenmaku no Gijutu (Technologies of Transparent Electroconductive Films)”, published by Ohmsha, Ltd. (1999), and the references noted in these literatures.

The electrode of the organic electromagnetic wave absorbing and photoelectric conversion part in the invention will be described in more detail. The organic layer of the photoelectric conversion film is held between the pixel electrode film and the counter electrode film and can contain inter-electrode materials. The pixel electrode film is such an electrode film that has the charge accumulating, transporting and reading out part therein and is formed above the substrate, and the pixel electrode is generally divided into respective pixels. This is because the signal charge obtained through conversion by the photoelectric conversion film is read out per respective pixels on the charge accumulating, transporting and signal reading out circuit substrate.

The counter electrode has such a function that upon holding the photoelectric conversion film with the pixel electrode film, it outputs signal charge having the opposite polarity to the signal charge. It is not necessary that the output of the signal charge is divided into respective pixels, and therefore the counter electrode can be formed commonly to the pixels. Therefore, the counter electrode is sometimes referred to as a common electrode film.

The photoelectric conversion film is disposed between the pixel electrode film and the counter electrode film. The photoelectric conversion function is exerted by the photoelectric conversion film with the pixel electrode film and the counter electrode film.

Examples of the constitution of the photoelectric conversion laminated layer include such a constitution that a pixel electrode film (which is basically a transparent electrode film), a photoelectric conversion film, and a counter electrode film (which is a transparent electrode film) are laminated on a substrate, but the invention is not limited to the constitution.

In the case where two organic layers are laminated on the substrate, examples thereof include such a constitution that a pixel electrode film (which is basically a transparent electrode film), a photoelectric conversion film, a counter electrode film (which is a transparent electrode film), an interlayer dielectric film, a pixel electrode film (which is basically a transparent electrode film), a photoelectric conversion film, and a counter electrode film (which is a transparent electrode film) are laminated on a substrate.

The material of the transparent electrode for constituting the photoelectric conversion part of the invention is preferably such a material that can be formed into a film by a plasma-free film forming apparatus, such as an EB vapor deposition apparatus and a pulse laser vapor deposition apparatus. Preferred examples thereof include a metal, an alloy, a metallic oxide, a metallic nitride, a metallic boride, an organic electroconductive compound, and a mixture thereof, and specific examples thereof include an electroconductive metallic oxide, such as tin oxide, zinc oxide, indium oxide, indium zinc oxide (IZO), indium tin oxide (ITO) and indium tungsten oxide (IWO), a metal, such as gold, platinum, silver, chromium, nickel and aluminum, a mixture or a laminated material of a metal and an electroconductive metallic oxide, an inorganic electroconductive substance, such as copper iodide and copper sulfide, an organic electroconductive material, such as polyaniline, polythiophene and polypyrrole, and a laminated body of these materials with ITO. Furthermore, the materials disclosed in Y. Sawada, “Tomei Doudenmaku no Shin-tenkai (New Developments of Transparent Electroconductive Films)”, published by CMC Press (1999), Y. Sawada, “Tomei Doudenmaku no Shin-tenkai II (New Developments of Transparent Electroconductive Films II)”, published by CMC Press (2002), Japan Society for the Promotion of Science, Toumei Doudenmaku no Gijutu (Technologies of Transparent Electroconductive Films)”, published by Ohmsha, Ltd. (1999) can be used.

Particularly preferred examples of the material of the transparent electrode include ITO, IZO, SnO₂, ATO (antimony-doped tin oxide), ZnO, AZO (aluminum-doped zinc oxide), GZO (gallium-doped zinc oxide) and TiO₂, FTO (fluorine-doped tin oxide). The transparent electrode preferably has a light transmittance of 60% or more, more preferably 80% or more, further preferably 90% or more, and still further preferably 95% or more, at the wavelength of the photoelectric conversion light absorption peak of the photoelectric conversion film contained in the photoelectric conversion device containing the transparent electrode. The preferred range of the surface resistance of the transparent electrode varies depending on whether the transparent electrode is a pixel electrode or a counter electrode and whether the charge accumulating, transporting and reading out part has a CCD structure or a CMOS structure. In the case where the transparent electrode is used as a counter electrode and has a charge accumulating, transporting and reading out part having a CMOS structure, the surface resistance is preferably 10,000 Ω per square or less, and more preferably 1,000 Ω per square or less. In the case where the transparent electrode is used as a counter electrode and has a charge accumulating, transporting and reading out having a CCD structure, the surface resistance is preferably 1,000 Ω per square or less, and more preferably 100 Ω per square or less. In the case where the transparent electrode is used as a pixel electrode, the surface resistance is preferably 1,000,000 Ω per square or less, and more preferably 100,000 Ω per square or less.

The conditions upon producing the transparent electrode will be described. The temperature of the substrate upon forming the transparent electrode is preferably 500° C. or less, more preferably 300° C. or less, further preferably 200° C. or less, and still further preferably 150° C. or less. Upon forming the transparent electrode, a gas may be introduced. The gas is not particularly limited in species thereof, and for example, argon, helium, oxygen or nitrogen can be used. A mixed gas of these gases may also be used. In the case where an oxide is used as the material, oxygen is preferably used for preventing oxygen defects from occurring.

(Inorganic Layer)

The inorganic layer as the electromagnetic wave absorbing and photoelectric conversion part will be described. In this case, light passing through the organic layer as an upper layer is subjected to photoelectric conversion in the inorganic layer. As the inorganic layer, a pn-junction or a pin-junction of crystalline silicon, amorphous silicon or a compound semiconductor, such as GaAs, is generally used. The method disclosed in U.S. Pat. No. 5,965,875 can be used as the laminated structure. That is, in the structure, a laminated light receiving part is formed by utilizing the wavelength dependency of the absorption coefficient of silicon, and color separation is effected in the depth direction of the light receiving part. In this case, the color separation is effected depending on the depth of silicon, to which the light penetrates, and therefore, the spectral ranges to be detected by the respective light receiving parts laminated become broad. However, by using the organic layer as an upper layer, in other words, by detecting light passing through the organic layer in the depth direction of silicon, the color separation capability is considerably improved. In the case where a G layer is formed in the organic layer, particularly, the light passing through the organic layer contains only blue light and green light, and thus the light to be separated in the depth direction of silicon contains only blue light and green light, whereby the color separation capability is considerably improved. In the case where the organic layer contains a B layer or an R layer, the color separation capability can also be considerably improved by appropriately selecting the electromagnetic wave absorbing and photoelectric conversion part in the depth direction of silicon. In the case where two organic layers are present, the electromagnetic wave absorbing and photoelectric conversion part of silicon may basically function for only one color, whereby favorable color separation can be effected.

The inorganic layer preferably has such a structure that plural photodiodes for respective pixels are laminated in the depth direction of a semiconductor substrate, color signals corresponding to signal charge formed in the plural photodiodes with light absorbed by the respective diodes are output. The plural photodiodes preferably contain the first photodiodes provided at the depth where blue light is absorbed, and the second photodiodes provided at the depth where red light is absorbed, and such a color signal read-out circuit is preferably provided that reads out color signals corresponding to the signal charge generated in the respective photodiodes. According to the constitution, color separation can be effected by using no color filter. In some cases, light of negatively sensitive component can also be detected to enable color imaging with good color reproducibility. It is preferred in the invention that the junction part of the first photodiode is formed to a depth of about 0.2 μm or less from the surface of the semiconductor substrate, and the junction part of the second photodiode is formed to a depth of about 2 μm or less from the surface of the semiconductor substrate.

The inorganic layer will be described in more detail. Examples of the preferred constitution of the inorganic layer include a light-receiving device of a photoconductive type, a pn-junction type, a Schottky junction type, a pin-junction type or an MSM (metal-semiconductor-metal) type, and a phototransistor type light-receiving device. In the invention, such a light-receiving device is preferably used that plural first conductive type regions and second conductive type regions having a conductive type contrary to the first conductive type are alternately laminated, and the junction surfaces between the first conductive type and the second conductive type are formed at depths that are suitable for effecting photoelectric conversion of light of plural wavelength ranges different from each other. As the single semiconductor substrate, single crystal silicon is preferably used, and color separation can be effected by utilizing the dependency of absorption wavelength characteristics on the depth direction of the silicon substrate.

As the inorganic semiconductor, such an inorganic semiconductor as an InGaN system, an InAlN system, an InAlF system and an InGaAlP system can be used. The InGaN inorganic semiconductor is adjusted to have a maximum absorption value in a blue wavelength range by appropriately changing the content of In. That is, the InGaN inorganic semiconductor has a composition InₓGa₁₋ₓN (0<x<1). These compound semiconductors are produced by a metal-organic chemical vapor deposition (MOCVD) method. The nitride semiconductor of the InAlN system using Al, which is the Group 13 element as similar to Ga, can be used as a short wavelength light receiving part as similar to the InGaN system. InAlP and InGaAlP, which match a GaAs substrate, can also be used.

The inorganic semiconductor may have a buried structure. The buried structure has such a constitution that both ends of a short wavelength light receiving part are covered with a semiconductor that is different from the short wavelength light receiving part. The semiconductor covering the both ends is preferably a semiconductor having a band gap wavelength that is shorter than or equivalent to the band gap wavelength of the short wavelength light receiving part.

The organic layer and the inorganic layer may be bonded in any mode. An insulating layer is preferably provided between the organic layer and the inorganic layer for electrically insulating them.

The junction preferably contains an order of npn or pnpn from the light incident side. Particularly, in the case where a p-layer is provided on the surface, and the potential on the surface is increased, holes and dark current formed around the surface can be trapped, and therefore, a pnpn-junction is more preferably used.

The photodiode is formed by sequentially diffusing from a surface of a p-type silicon substrate. An n-type layer, a p-type layer, an n-type layer and a p-type layer are formed from larger depths in this order, whereby pn-junction diodes are formed with four layers of pnpn in the depth direction. Light having a longer wavelength incident on the surface of the diode penetrates into a larger depth, i.e., the incident wavelength and the attenuation coefficient show a function that is intrinsic to silicon, and accordingly, the photodiode is designed in such a manner that the pn-junction surfaces cover the respective wavelength ranges of visible light. Similarly, an n-type layer, a p-type layer and an n-type layer are formed in this order, whereby junction diodes are formed with three layers of npn in the depth direction. The light signal is taken out from the n-type layer, and the p-type layer is grounded.

Extraction electrodes are provided in the regions, respectively, to which a reset voltage is applied, whereby the regions are depleted to minimize the capacities of the junction parts. According to the operation, the capacity formed at the junction surface can be extremely small.

(Auxiliary Layer)

The device of the invention preferably has an ultraviolet ray absorbing layer and/or an infrared ray absorbing layer as the uppermost layer of the electromagnetic wave absorbing and photoelectric conversion layer. The ultraviolet ray absorbing layer can absorbs or reflects at least light having a wavelength of 400 nm or less, and preferably has an absorbance in a wavelength range of 400 nm or less of 50% or more. The infrared ray absorbing layer absorbs or reflects at least light having a wavelength of 700 nm or more, and preferably has an absorbance in a wavelength range of 700 nm or less of 50% or more.

The ultraviolet ray absorbing layer and the infrared ray absorbing layer are formed by the known method. For example, such a method has been known that a mordant layer containing a hydrophilic polymer, such as gelatin, casein, glue or polyvinyl alcohol, is provided on a substrate, and the mordant layer is added with or dyed with a colorant having an intended absorption wavelength to form a colored layer. Furthermore, such a method has also been known that uses a colored resin having a certain kind of colorant dispersed in a transparent resin. For example, as disclosed in JP-A-58-46325, JP-A-60-78401, JP-A-60-184202, JP-A-60-184203, JP-A-60-184204 and JP-A-60-184265, a colored resin film of a polyamino resin mixed with a colorant can be used. A coloring agent using a polyimide resin having photosensitivity can also be used.

A colorant may be dispersed in an aromatic polyamide resin having a photosensitive group in the molecule and obtained by curing at 200° C. or less disclosed in JP-B-7-113685. A colored resin having a pigment disclosed in JP-B-7-69486 dispersed therein can be used.

In the invention, a dielectric multilayer film is preferably used owing to its sharp wavelength dependency of light transmission.

The electromagnetic wave absorbing and photoelectric conversion parts are preferably separated from each other with an insulating layer. The insulating layer can be formed by using a transparent insulating material, such as glass, polyethylene, polyethylene terephthalate, polyether sulfone and polypropylene. Silicon nitride and silicon oxide can also be preferably used. Silicon nitride formed into a film by plasma CVD is preferably used in the invention owing to its high denseness and high transparency.

A protective layer or a sealing layer may be provided for preventing oxygen and water from being in contact. Examples of the protective layer include a diamond thin film, an inorganic material film, such as a metallic oxide and a metallic nitride, a polymer film, such as a fluorine resin, poly-p-xylene, polyethylene, a silicone resin and a polystyrene resin, and a photocurable resin film. It is also possible that the device is covered with glass, a gas-impermeable resin or a metal and sealed with a suitable sealing resin to form a packaging. In this case, a high water-absorbing substance may be disposed in the packaging.

It is a preferred embodiment that a microlens array is provided above the light-receiving device to improve the light condensing efficiency.

(Charge Accumulating, Transporting and Reading Out Part)

With respect to the charge accumulating, transporting and reading out part, JP-A-58-103166, JP-A-58-103165 and JP-A-2003-332551 can be referred. A constitution having MOS transistors formed on a semiconductor substrate for respective pixels, and a constitution having CCD as a device can be appropriately employed. For example, in the case of a photoelectric conversion device using MOS transistors, charge is generated in a photoconductive film with incident light passing through an electrode, and the charge moves within the photoconductive film to the electrode through an electric field between the electrodes generated by applying a voltage to the electrodes and further moves to the charge accumulating part of the MOS transistor, whereby the charge is accumulated in the charge accumulating, part. The charge thus accumulated in the charge accumulating part moves to the charge read-out part through switching of the MOS transistor, and is output as an electric signal. Accordingly, a full color image signal is input to the solid image pickup device including a signal processing part.

A certain amount of bias charge is injected to an accumulating diode (refresh mode), and after accumulating charge (photoelectric conversion mode), the signal charge can be read out. The light receiving device itself can be used as the accumulating diode, and an accumulating diode may be separately provided.

The reading out operation of signal will be described in more detail. An ordinary color reading out circuit can be used for the reading out operation of signal. The signal charge or signal current obtained through photoelectric conversion in the light receiving part is accumulated in the light receiving part itself or a capacitor separately provided. The accumulated charge is read out with positional information of the selected pixel by the measure of a MOS image pickup device using the X-Y address system (so-called a CMOS sensor). Another example of the address selection system is that the pixels are selected one by one using a multiplexer switch and a digital shift resister, and the charge is read out as a signal voltage (or charge) to the common output line. As such an image pickup device that is two-dimensionally arrayed with X-Y address operation, a CMOS sensor has been known. In this device, a switch provided at a pixel connected to a intersecting point of the X and Y axes is connected to a vertical shift resister, and upon turning on the switch by a voltage from a vertical scanning shift resister, the signal read out from the pixels on the same line is read out to the output line in the column direction. The signal is sequentially read out from the output end through a switch driven by a horizontal scanning shift resister.

For reading out the output signal, a floating diffusion detector or a floating gate detector can be used. The S/N ratio can be improved by using such a measure as the provision of a signal amplification circuit in pixel parts or the use of a correlated double sampling method.

As the signal process, gamma correction with an ADC circuit, digitalization with an AD converter, brightness signal process and a color signal process can be effected. Examples of the color signal process include white balance process, color separation process and color matrix process. Upon applying to NTSC signal, RGB signal may be converted to YIQ signal.

The charge transporting and reading out part necessarily has a charge mobility of 100 cm²/V·sec or more, and the mobility can be obtained by selecting the material from semiconductors of the Group IV, Group III-V and Group II-VI. Among these, a silicon semiconductor is preferably used because of the advanced fine processing techniques therefor and the low cost. A CMOS device and a CCD device are particularly preferred in the invention, and it is often the case that a CMOS device is preferred from the standpoint of high speed read out, pixel addition, partial read out and power consumption.

(Connection)

The plural contact parts for connecting the electromagnetic wave absorbing and photoelectric conversion parts and the charge transporting and reading out part may be formed with any metal, and preferably selected from copper, aluminum, silver, gold, chromium and tungsten, and particularly copper. The contact parts are necessarily provided between the charge transporting and reading out part and each of the plural electromagnetic wave absorbing and photoelectric conversion parts. In the case where a laminated structure of plural photosensitive units for blue, green and red light, each of the blue light read out electrode and the charge transporting and reading out part, the green light read out electrode and the charge transporting and reading out part, and the red light read out electrode and the charge transporting and reading out part are necessarily connected, respectively.

(Process)

The laminated photoelectric conversion device according to the invention can be produced by the so-called microfabrication process, which is known in the art and used for producing an integrated circuit. In the process, basically, such procedures are repeated that contain pattern wise exposure with active light of an electron beam (such as i- or g-emission line of mercury and excimer laser, as well as X-ray and electron beam), pattern formation by development and/or burning, disposition of device forming materials (such as coating, vapor deposition, sputtering and CV), and removal of the materials on the non-pattern part (such as heat treatment and dissolution treatment).

(Application)

The chip size of the device of the invention may be the brownie size, the 135 size, the APS size and 1/1.8 inch, and may be further smaller sizes. The pixel size of the laminated photoelectric conversion device of the invention is expressed in terms of a circle-equivalent diameter corresponding to the maximum area of the plural electromagnetic wave absorbing and photoelectric conversion parts. The pixel size is not particularly limited and is preferably from 2 to 20 μm, more preferably from 2 to 10 μm, and particularly preferably from 3 to 8 μm.

In the case where the pixel size exceeds 20 μm, the resolution is deteriorated, and in the case where the pixel size is less than 2 μm, the resolution is deteriorated due to radio interference among the pixels.

The photoelectric conversion device of the invention can be used in a digital still camera and is preferably used in a television camera. Other examples of the application thereof include a digital video camera, a security camera for various locations (such as a office building, a car parking, a branch and an unattended contracting machine of a financial company, a mall, a drug store, an outlet mall, a department store, a pachinko parlor, a karaoke booth, an amusement parlor and a hospital), various kinds of sensors (such as a video intercom, a sensor for personal authentication system, a sensor for factory automation, a household robot, an industrial robot and a piping inspection system), a medical sensor (such as an endoscope and a fundus camera), a video conference camera, a video phone, a camera for portable phone, a safety system for automobile (such as a backside sensor, an impact prediction system and a lane holding system), and a sensor for video game.

Among these, the photoelectric conversion device of the invention is preferably applied to a television camera because the device of the invention attains reduction in size and weight of a television camera by using no color separation optical system. Furthermore, the device of the invention is suitable for a television camera for high-definition broadcast including a television camera for digital high-definition broadcast.

Another advantage of the photoelectric conversion device of the invention is further high sensitivity and resolution by using no optical low-pass filter.

The photoelectric conversion device of the invention can be reduced in thickness and can be omitted with a color separation optical system, and therefore, only one camera can be applied to various imaging situations with various sensitivities, spectral sensitivities and color reproducibilities (for example, environments different in brightness including daytime and nighttime, and environment different in motion including a stationary object and a moving object) by exchanging the photoelectric conversion devices according to the invention. Accordingly, a photographer can be reduced in imposition by avoiding plural cameras held at once. Examples of the photoelectric conversion devices to be exchanged include, in addition to those having been described, photoelectric conversion devices for infrared imaging, monochromatic imaging, and various dynamic ranges.

The television camera according to the invention can be produced, for example, by referring to Chapter 2 of “Television Camera no Sekkei Gijutu (Design Technique of Television Camera)”, edited by the Institute of Image Information and Television Engineers (Japan), published by Corona Publishing Co., Ltd. on Aug. 20, 1999 (ISBN 4-339-00714-5) in such a manner that the color separation optical system and the image pickup device in the basic structure of television camera shown in FIG. 2.1 are replaced by the photoelectric conversion device of the invention.

The laminated light receiving device may be arrayed, whereby it can be not only used as an image pickup device, but also used by itself as an optical sensor, such as a biosensor and a chemical sensor, and a color light receiving device.

### EXAMPLE

The invention will be described in more detail with reference to the following examples, but the invention is not limited thereto.

### Example 1

A cleaned ITO substrate was placed in a vapor deposition apparatus, on which a p-type photoelectric conversion material (Compound 1) was vapor-deposited to 100 nm, and an n-type photoelectric conversion material (Compound 2) was further vapor-deposited to 100 nm, so as to form an organic pn-laminated photoelectric conversion layer. A patterned mask (having a luminescent area of 2 mm×2 mm) was placed on the organic thin film, on which aluminum was vapor-deposited to 500 nm in a vapor deposition apparatus. The assembly was then sealed with a desiccant to produce a photoelectric conversion device for green light (Device No. 101).

### Example 2

The same procedures as the Device No. 101 in Example 1 were repeated except that after vapor-depositing the p-type photoelectric conversion material (Compound 1), the n-type photoelectric conversion material (Compound 2) was further vapor-deposited thereon to 80 nm, and further the electron transporting material No. 26 was vapor-deposited to 70 nm. The assembly was sealed with an aluminum electrode in the same manner as in Example 1 to produce a photoelectric conversion device (Device No. 102).

### Comparative Example

The same procedures as the Device No. 101 in Example 1 were repeated except that after vapor-depositing the p-type photoelectric conversion material (Compound 1), Alq (aluminum quinoline) as an n-type compound was further vapor-deposited thereon to 100 nm. The assembly was sealed with an aluminum electrode in the sane manner as in Example 1 to produce a photoelectric conversion device (Device No. 103).

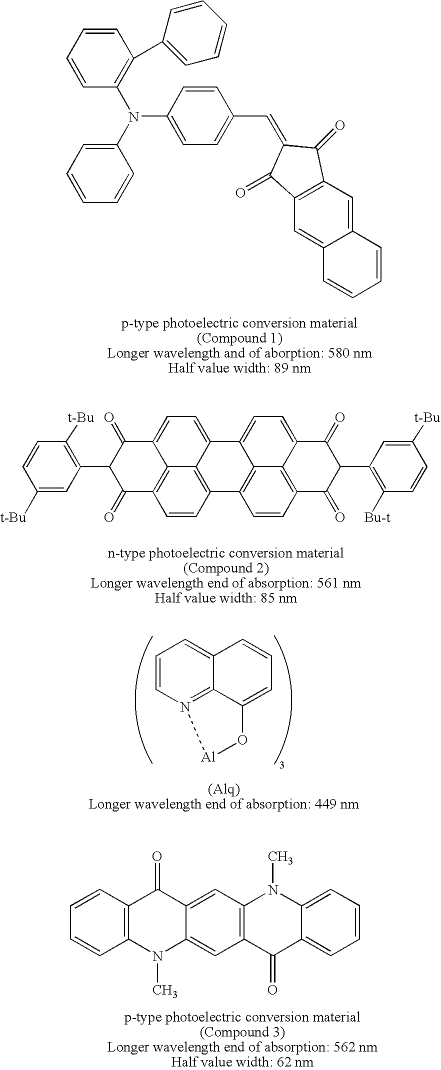

The devices were evaluated in the following manner.

A bias voltage of 10 V was applied to the ITO electrode as a negative electrode and the aluminum electrode as a positive electrode.

The wavelength dependency of external quantum efficiency (IPCE) was evaluated by using a solar cell evaluation apparatus, produced by Optel Co., Ltd. The results obtained are shown in Table 1 below.

TABLE 1

| | | | | External | Photoelectric |
|---|---|---|---|---|---|
| | | | | quantum | conversion |
| | | | Electron | efficiency | spectrum λₘₐₓ |
| | p-type | n-type | transporting | (applied | (half value |
| Device No. | compound | compound | material | voltage) | width) |
| Device No. 101 | Compound 1 | Compound 2 | none | 2.5% (15 V) | 520 nm (90 nm) |
| Device No. 102 | Compound 1 | Compound 2 | No. 26 | 4.0% (12 V) | 523 nm (90 nm) |
| Device No. 103 | Compound 1 | Alq | none | 2.0% (15 V) | 530 nm, 400 nm |

Table 1 shows the maximum value and the half value width of the photoelectric conversion spectrum obtained from the result of wavelength dependency of IPCE, and also shows the external quantum efficiency of the maximum value and the absolute value of the reverse bias voltage applied upon measurement. In the case where the longer wavelength ends of the p-type compound and the n-type compounds are largely different from each other as in the Device No. 103, the photoelectric conversion spectrum fails to show a single sharp peak but has sensitivity in the other range than green light (blue light) to provide deteriorated color reproducibility. In the case where the longer wavelength ends of the p-type compound and the n-type compounds substantially agree with each other (difference in longer wavelength end; 19 nm) as in the Devices Nos. 101 and 102, on the other hand, a single sharp photoelectric conversion spectrum can be obtained, and furthermore, favorable results are obtained in external quantum efficiency. In the device using the electron transporting material No. 26, which has an exciton blocking function, the external quantum efficiency is further improved to provide good photoelectron conversion characteristics. The Devices Nos. 101 and 102 according to the invention exhibit good durability in comparison to the Device No. 103.

### Example 3

Devices were produced in the same manners as in Examples 1 and 2, respectively, except that Quinacridone Compound 1 was used instead of the Compound 1, and the thickness of the n-type Compound 2 was changed to 30 nm (Device Nos. 301 and 302). The devices had a sharp photoelectric conversion spectrum and showed good photoelectric conversion efficiency.

TABLE 2

| | | | | External | Photoelectric |
|---|---|---|---|---|---|
| | | | | quantum | conversion |
| | | | Electron | efficiency | spectrum λₘₐₓ |
| | p-type | n-type | transporting | (applied | (half value |
| Device No. | compound | compound | material | voltage) | width) |
| Device No. 301 | Compound 3 | Compound 2 | none | 5.3% (12 V) | 540 nm (95 nm) |
| Device No. 302 | Compound 3 | Compound 2 | No. 26 | 6.2% (12 V) | 543 nm (98 nm) |

A three-layer laminated image pickup device shown in FIG. 1 can be produced by combining the aforementioned device with devices for light other than green light, i.e., blue and red light, having the similar design.

A device having an organic layer and an inorganic layer as mixture shown in FIG. 2 can be produced by combining a device having green spectral sensitivity using the compound of the invention with inorganic layers having red spectral sensitivity and blue spectral sensitivity, respectively.

The photoelectric conversion film, the photoelectric conversion device and the image pickup device of the invention have a narrow half-value width of absorption to provide excellent color reproducibility, and have high photoelectric conversion efficiency and excellent durability. The BGR three-layer laminated solid image pickup device according to the invention further has the following advantages in addition to the aforementioned ones.
Owing to the three-layer structure, it is free of moire, has high resolution without necessity of an optical low-pass filter, is free of color blur, and is free of quasi-signal with simple signal processing. In the case of CMOS devices, image mixture is facilitated, and partial read-out is also facilitated.
Owing to an aperture ratio of 100% and unnecessity of microlens, it has no limitation in exit pupil distance with no shading. Therefore, it is suitable for a lens-exchangeable camera, and a lens therefor can be reduced in profile.
Owing to unnecessity of microlens, it can be sealed with glass by charging an adhesive, and thus a package thereof can be reduced in profile and improved in yield to reduce costs.
Owing to the use of an organic colorant, it has high sensitivity without an IR filter to reduce flare.

The entire disclosure of each and every foreign patent application from which the benefit of foreign priority has been claimed in the present application is incorporated herein by reference, as if fully set forth.

What is claimed is:

1. A photoelectric conversion device comprising;
an organic photoelectric conversion film intervening between at least two electrodes, the organic photoelectric conversion film comprising a positive hole transporting photoelectric conversion film and an electron transporting photoelectric conversion film,
wherein each of the positive hole transporting photoelectric conversion film and the electron transporting photoelectric conversion film has absorption in a visible range, and a difference in wavelength between longer wavelength ends of absorption of the positive hole transporting photoelectric conversion film and the electron transporting photoelectric conversion film is 50 nm or less.

2. The photoelectric conversion device as claimed in claim 1,
wherein a film absorption spectrum of the organic photoelectric conversion film has an absorption maximum on the longest wavelength side having a half-value width of from 50 to 150 nm.

3. The photoelectric conversion device as claimed in claim 1,
wherein the organic photoelectric conversion film has a film absorption spectrum in at least one range of blue light, green light and red light in a wavelength range of 400 nm or more, and the absorption spectrum in the range has an absorption maximum having a maximum value of three times or more a maximum value of an absorption maximum in a wavelength range outside the range.

4. The photoelectric conversion device as claimed in claim 1,
wherein the organic photoelectric conversion film has a photoelectric conversion spectrum having a maximum value at a wavelength of from 420 to 480 nm, from 510 to 570 nm, or from 600 to 660 nm.

5. The photoelectric conversion device as claimed in claim 1, wherein the film of the electron transport material is in a crystalline state.

6. The photoelectric conversion device as claimed in claim 1,
wherein an ionization potential (Ip₁) and an electron affinity (Ea₁) of the positive hole transporting photoelectric conversion film and an ionization potential (Ip₂) and an electron affinity (Ea₂) of the electron transporting photoelectric conversion film satisfy relationships Ip₁<Ip₂ and Ea₁<Ea₂.

7. The photoelectric conversion device as claimed in claim 1,
wherein the photoelectric conversion device further comprises at least one charge transporting layer transporting positive holes or electrons formed in the organic photoelectric conversion layer, and the charge transporting layer has absorption having a longer wavelength end at a wavelength shorter than an absorption maximum wavelength of the organic photoelectric conversion film.

8. The photoelectric conversion device as claimed in claim 7,
wherein the charge transporting layer comprises a compound represented by the following general formula (I)
L [symbol] A)ₘ (I)
wherein A represents a heterocyclic ring containing two or more aromatic heterocyclic rings condensed to each other, provided that plural heterocyclic rings represented by A are the same as or different from each other; m represents an integer of 2 or more; and L represents a linking group.

9. The photoelectric conversion device as claimed in claim 7,
wherein the charge transporting layer comprises a compound represented by the following general formula (III) 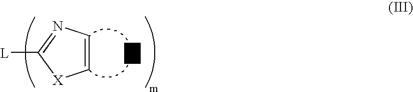
wherein X represents O, S, Se, Te or N—R; R represents a hydrogen atom, an aliphatic hydrocarbon group, an aryl group or a heterocyclic group; Q₃ represents an atomic group forming an aromatic heterocyclic ring; m represents an integer of 2 or more; and L represents a linking group.

10. An image pickup device comprising at least one of the photoelectric conversion device as claimed in claim 1.

11. The image pickup device as claimed in claim 10,
wherein the photoelectric conversion device has a maximum of a photoelectric conversion spectrum in a green light range.

12. The image pickup device as claimed in claim 10, wherein the image pickup device has at least three of the photoelectric conversion devices, and the photoelectric conversion devices have maxima of photoelectric spectra in a blue light range, a green light range and a red light range, respectively.

13. A method for applying an electric field of 10 V/m to 1×10¹² v/m to a photoelectric conversion device as claimed in claim 1.

14. A method for applying an electric field of 10 V/m to 1×10¹² V/m to an image pickup device as claimed in claim 10.

15. A device being applied with an electric field of 10 V/into 1×10¹² V/m, the device being the photoelectric conversion device as claimed in claim 1.

16. A device being applied with an electric field of 10 V/m to 1×10¹² V/m, the device being the image pickup device as claimed in claim 10.

17. A device comprising at least two electromagnetic wave absorbing and photoelectric conversion parts, at least one of the parts comprising the image pickup device as claimed in claim 10.

18. The device as claimed in claim 17, wherein said at least two electromagnetic wave absorbing and photoelectric conversion parts have a laminate structure of at least two layers.

19. The device as claimed in claim 18, wherein an upper layer of said at least two layers comprises a portion capable of photoelectric conversion by absorbing green light.

20. A device comprising at least three electromagnetic wave absorbing and photoelectric conversion parts, at least one of the parts comprising the image pickup device as claimed in claim 10.

21. The device as claimed in claim 20,
wherein said at least three electromagnetic wave absorbing and photoelectric conversion parts have a laminate structure of at least three layers,
and an upper layer of said at least three layers comprises a portion capable of a photoelectric conversion by absorbing green light.

22. The device as claimed in claim 20,
wherein at least two of said at least three electromagnetic wave absorbing and photoelectric conversion parts are formed by inorganic layers.

23. The device as claimed in claim 20,
wherein at least two of said at least three electromagnetic wave absorbing and photoelectric conversion parts are formed in a silicon substrate.
